(19) United States
(12) Patent Application Publication
(10) Pub. No.: US 2014/0273362 A1
(43) Pub. Date: Sep. 18, 2014

(54) METHOD FOR MANUFACTURING THIN FILM TRANSISTOR AND ARRAY SUBSTRATE

(71) Applicant: BOE TECHNOLOGY GROU CO., LTD., Beijing (CN)

(72) Inventors: Tao Gao, Beijing (CN); Ce Ning, Beijing (CN); Hang Yu, Beijing (CN); Fangzhen Zhang, Beijing (CN)

(73) Assignee: BOE TECHNOLOGY GROUP CO., LTD., Beijing (CN)

(21) Appl. No.: 14/126,000

(22) PCT Filed: Dec. 14, 2012
(86) PCT No.: PCT/CN2012/086608

§ 371 Date: Dec. 13, 2013

(30) Foreign Application Priority Data
Jul. 2, 2012 (CN) 201210228691.1

(51) Int. Cl. H01L 27/12; H01L 29/49

(52) U.S. Cl. CPC H01L 27/1259; H01L 29/4908
USPC 438/158

(57) ABSTRACT

The embodiments of the present invention provide a method for manufacturing a thin film transistor and a method for manufacturing an array substrate. The method for manufacturing the thin film transistor comprises: forming a gate electrode on a transparent substrate; forming a gate insulation layer; forming a transparent semiconductor film and patterning the transparent semiconductor film to form a semiconductor layer with photoresist being remained over the semiconductor layer; from a side of the transparent substrate opposite to the side on which the gate electrode is formed, exposing and developing the remained photoresist by using the gate electrode as a mask to form a channel position photoresist part corresponding to the gate electrode; forming a source/drain metal film and lifting off the channel position photoresist part and the source/drain metal film located over the channel position photoresist part; and patterning the remained source/drain metal film to form a source electrode and a drain electrode. The embodiments of the present invention are suitable to manufacture the product or device containing thin film transistors.

### TECHNICAL FIELD

The embodiments of the present invention relates to a method for manufacturing a thin film transistor and a method for manufacturing an array substrate.

### BACKGROUND

Thin film transistor liquid crystal displays (referred as to TFT-LCDs) have been prevalent in the current flat panel display market due to their advantages such as small volume, low power consumption, no radiation, and so on.

In the method for manufacturing a TFT-LCD in the prior art, the source electrode and the drain electrode of a thin film transistor are aligned by alignment marks provided on the respective comers on a plane, such an alignment method suffers from the problem that the precise of the alignment is low, and there will be alignment shift between the gate electrode and the source electrode and also between the gate electrode and the drain electrode, resulting in no-uniform capacitance between the source/drain electrodes and the gate electrode, and thus causing the chrominance deviation of the liquid crystal display and degradation of the product quality.

### SUMMARY

The embodiments of the present invention provide a method for manufacturing a thin film transistor and a method for manufacturing an array substrate by which the alignment precise between the source/drain electrodes and the gate electrode is improved and thus the product quality is improved.

To achieve this object, the embodiments of the present invention employ the technical solutions as follows:

According to one aspect of an embodiment of the present invention, a method for manufacturing a thin film transistor comprises: forming a gate electrode on a transparent substrate; forming a gate insulation layer; forming a transparent semiconductor film and patterning the transparent semiconductor film to form a semiconductor layer with photoresist being remained over the semiconductor layer; from a side of the transparent substrate opposite to the side on which the gate electrode is formed, exposing and developing the remained photoresist by using the gate electrode as a mask to form a channel position photoresist part corresponding to the gate electrode; forming a source/drain metal film and lifting off the channel position photoresist part and the source/drain metal film located over the channel position photoresist part; and patterning the remained source/drain metal film to form a source electrode and a drain electrode.

In one example, the method further comprises, after forming the transparent semiconductor film and prior to patterning the semiconductor film, forming a doped semiconductor film on the semiconductor film; when the semiconductor film is patterned, the doped semiconductor film is patterned at the same time to form a doped semiconductor layer, and a shape of the semiconductor layer is identical with a shape of the doped semiconductor layer; and the method further comprises, after lifting off the channel position photoresist part and the source/drain metal film thereon and prior to patterning the remained source/drain film, etching the doped semiconductor layer corresponding to the gate electrode to expose the semiconductor layer and form a doped semiconductor pattern.

In one example, forming of the doped semiconductor layer comprises: applying photoresist on the doped semiconductor film and exposing, developing to form a photoresist fully remaining area corresponding to a pattern area of the semiconductor layer and a photoresist fully removing area through which the doped semiconductor film is exposed; etching the semiconductor film and the doped semiconductor film in the photoresist fully removing area to form the semiconductor layer and the doped semiconductor layer.

In one example, the method further comprises, prior to the forming the source/drain metal film, forming a doped semiconductor film on the substrate on which the channel position photoresist part is formed; upon lifting off the channel position photoresist part and the source/drain metal film thereon, the doped semiconductor film between the channel position photoresist part and the source/drain metal film is also lift off at the same time; and upon patterning the remained source/drain metal film to form the source electrode and the drain electrode, the doped semiconductor film is patterned at the same time to form a doped semiconductor pattern, the doped semiconductor pattern being identical with the source electrode and the drain electrode in shape.

According to one aspect of the embodiment of the present invention, a method for manufacturing an array substrate comprises: forming a gate metal layer on a transparent substrate, the gate metal layer comprising a gate line and a gate electrode of a thin film transistor; forming a gate insulation layer; forming a transparent semiconductor film and patterning the semiconductor film to form a semiconductor layer with photoresist being remained over the semiconductor layer; from a side of the transparent substrate opposite to the side on which the gate electrode is formed, exposing and developing the remained photoresist with the gate electrode as a mask, to form a channel position photoresist part corresponding to the gate electrode; forming a source/drain metal film and lifting off the channel position photoresist part and the source/drain metal film thereon; and patterning the remained source/drain metal film to form a source/drain metal layer, wherein the source/drain metal layer comprises a source electrode and a drain electrode of the thin film transistor and a data line.

In one example, the method further comprises, before the forming the source/drain metal film, forming a transparent conductive film on the substrate on which the channel position photoresist part is formed; forming of the source/drain metal film is to form the source/drain metal film on the transparent conductive film; upon lifting off the channel position photoresist part and the source/drain metal film thereon, the transparent conductive film between the channel position photoresist part and the source/drain metal film is also lift off; and upon patterning the remained source/drain metal film to form the source/drain metal layer, the transparent conductive film is also patterned at the same time to form a pixel electrode.

In one example, forming of the pixel electrode comprises: on the substrate on which the channel position photoresist part along with the transparent conductive film and the source/drain metal film thereon has been lift off, applying photoresist, and exposing and developing to form a photoresist fully remaining area, a photoresist half remaining area and a photoresist fully removing area, wherein the photoresist fully remaining area corresponds to a pattern area of the source/drain metal layer and a channel area, the photoresist half remaining area corresponds to a pattern area of the pixel electrode, and the photoresist fully removing area exposes the source/drain metal film; and etching the transparent conductive film and the source/drain metal film in the photoresist fully removing area to form the pixel electrode; removing the photoresist in the photoresist half remaining area by an ashing process, and etching the source/drain metal film exposed from the photoresist half remaining area to form the source/drain metal layer; and lifting off the photoresist in the photoresist fully remaining area.

In one example, the method further comprises, after forming the transparent semiconductor film and prior to patterning the semiconductor film, forming a doped semiconductor film on the semiconductor film; upon forming the semiconductor layer, the doped semiconductor film is also patterned at the same time to form a doped semiconductor layer, a shape of the semiconductor layer is identical with a shape of the doped semiconductor layer; and the method further comprises, after lifting off the channel position photoresist part along with the transparent conductive film and the source/drain metal film thereon and prior to patterning the remained source/drain metal film, etching the doped semiconductor layer corresponding to the gate electrode to expose the semiconductor layer and form the doped semiconductor layer.

In one example, patterning of the semiconductor layer and the doped semiconductor layer comprises: applying photoresist on the doped semiconductor film, and exposing and developing by using a mask plate to form a photoresist fully remaining area corresponding to a pattern area of the semiconductor layer and a photoresist fully removing area from which the doped semiconductor film is exposed; and etching the semiconductor film and the doped semiconductor film in the photoresist fully removing area to form the semiconductor layer and the doped semiconductor layer.

In the method for manufacturing a thin film transistor and the method for manufacturing an array substrate as provided by any of the embodiments of the present invention, the exposure process is carried out from a side of the transparent substrate opposite to the side on which the gate electrode is formed with the gate electrode as the mask, a channel position photoresist part corresponding to the gate electrode is formed after exposure, and then the channel position photoresist part and the source/drain metal film thereon are removed by a lifting-off process, to form the source electrode and the drain electrode aligning with the gate electrode precisely, and thus the product quality is improved.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 to FIG. 6 are structural schematic views of the respective stages in a method for manufacturing a thin film transistor as provided by an embodiment of the present invention;

FIG. 7 to FIG. 10 are structural schematic views of the respective stages in another method for manufacturing a thin film transistor as provided by an embodiment of the present invention;

FIG. 11 to FIG. 13 are structural schematic views of the respective stages in a method for manufacturing an array substrate as provided by an embodiment of the present invention; and

FIG. 14 to FIG. 18 are structural schematic views of the respective stages in another method for manufacturing an array substrate as provided by an embodiment of the present invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at lease one. The terms “comprise,” “include,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “right,” “left” and the like are only used to indicate relative position relationship, and when the position of the object which is described is changed, the relative position relationship may be changed accordingly.

Referring to FIG. 1 to FIG. 6, the method for manufacturing a thin film transistor as provided by an embodiment of the present invention comprises the steps as follows:

S11, as illustrated in FIG. 1, a gate electrode 11 is formed on a transparent substrate 001.

By the way of example, a gate metal film may be deposited on the transparent substrate 001 by using magnetron sputtering device, and then the gate electrode 11 is formed by a patterning process. The material for the gate metal film may be molybdenum, aluminum, copper, tungsten, or the like, or the gate metal film may be a composite layer composed of metals such as molybdenum, aluminum, copper, tungsten or the like.

S12, as illustrated in FIG. 2, a gate insulation layer 002 is formed on the substrate 001 on which the gate electrode 11 is formed.

By way of example, the gate insulation layer 002 may be deposited in the thickness of 2500˜4000 Å by a plasma enhanced chemical vapor deposition (PECVD) device, and the material for the gate insulation layer may be SiNx, SiOx, and the corresponding reaction gases in the plasma enhanced chemical vapor deposition device may be the mixture gas of SiH₄, NH₃, and N₂, or the mixed gas of SiH₂Cl₂, NH₃, and N₂.

S13, a transparent semiconductor film is formed on the gate insulation layer 002, and is subjected to a patterning process to form a semiconductor layer 003 while the photoresist 20a located above the semiconductor layer 003 is remained, as illustrated in FIG. 2.

The semiconductor film as used herein refers to such a film layer of semiconductor material covering the whole substrate, and the semiconductor layer as used herein refers to such a pattern formed by the semiconductor film after being subjected to a patterning process, and it may be also referred to as an active layer.

Specifically, the step S13 may comprise: forming a transparent semiconductor film on the gate insulation layer 002; applying photoresist on the semiconductor film, and exposing and developing by using a mask so that the photoresist 20a corresponding to a pattern area of the semiconductor layer is remained; etching the semiconductor film which is not covered by the photoresist to form the semiconductor layer 003. It is noted that in this step, the photoresist 20a corresponding to a pattern area of the semiconductor layer is unnecessary to be lift off here.

It is to be noted that as shown in FIG. 2, the pattern area of the semiconductor layer generally is larger than the pattern area of the gate electrode, that is to say, the pattern area of the gate electrode is covered by the pattern area of the semiconductor layer.

S14, the remained photoresist 20a is exposed and developed with the gate electrode 11 as a mask from a side of the transparent substrate 001 opposite to the side on which the gate electrode 11 is formed, to form a channel position photoresist part 20b corresponding to the gate electrode 11, as illustrated in FIG. 3.

In exposing from the other side of the transparent substrate 001 opposite to the side on which the gate electrode 11 is formed, light is incident from the lower side to the upper side in the figure, so that the gate electrode 11 can be used as a mask and it is unnecessary to use an additional mask plate. After development, a channel position photoresist part 20b can be formed to possess a profile the same as the gate electrode 11.

S15, a source/drain metal film is formed on the substrate having the channel position photoresist part 20b, and the channel position photoresist part 20b and the source/drain metal film thereon are lift off, then a source electrode and a drain electrode are formed by a patterning process.

By way of example, as illustrated in FIG. 4, on the substrate with the channel position photoresist part 20b, a source/drain metal film 101 with 2000˜3000 Å is deposited. The material for the source/drain metal film 101 may be a metal such as molybdenum, aluminum, copper, tungsten, or the like, or the material for the source/drain metal film 101 may be a composite film layer consisted by at least two metals as above indicated. As illustrated in FIG. 5, when lifting off the channel position photoresist part 20b, it is easy to the person skilled in the art to lift off the channel position photoresist part 20b by photoresist lifting-off technology since this portion is protruded from other surfaces, and also when lifting off the channel position photoresist part, a portion of the source/drain metal film attached to the channel position photoresist part is also removed, thus a channel aligned exactly with the gate electrode 11 can be obtained certainly. As illustrated in FIG. 6, the remaining portion of the source/drain metal film can be formed as the source electrode 12 and the drain electrode 13 by a patterning process.

Hereinafter, two methods for manufacturing a thin film transistor containing a doped semiconductor pattern are provide, these methods are based on the steps in the above mentioned manufacturing method, and thus only the difference from the above method is described. In the first method, the profile of a doped semiconductor pattern in the thin film transistor is the same as the profile obtained by removing the profile of the channel pattern from the profile of the semiconductor layer pattern; and in the second method, the doped semiconductor pattern in the thin film transistor is identical with the pattern of the source electrode and the drain electrode.

It is to be noted firstly, the doped semiconductor film in all the embodiments of the present invention refers to such a layer of semiconductor material film covering the entire substrate; the doped semiconductor layer refers to such a pattern of the doped semiconductor film in the semiconductor pattern area formed by a patterning process; and the doped semiconductor pattern refers to such a pattern finally formed by the doped semiconductor film in the thin film transistor or the array substrate.

Referring to FIG. 7 to FIG. 10, the first method for manufacturing the thin film transistor containing the doped semiconductor pattern is different from the above manufacturing method in that:

(1) During the process of the above step S13, after forming the transparent semiconductor film, and prior to forming the semiconductor layer by a patterning process, the method further comprises forming a doped semiconductor film on the semiconductor film; and when forming the semiconductor layer by a patterning process, a doped semiconductor layer is also formed, the shape of the semiconductor layer is identical with that of the doped semiconductor layer.

That is to say, in this embodiment, the step S13 comprises:

S131, a transparent semiconductor film is formed on the gate insulation layer 002, and a doped semiconductor film is formed on the semiconductor film.

By way of example the semiconductor film is deposited to the thickness of 800˜1500 Å by a PECVD device, and when depositing the semiconductor film, the reaction gas in the PECVD device is the mixture gas of SiH₄, NH₃, and N₂, or the mixed gas of SiH₂Cl₂, NH₃, and N₂.

By way of example, the doped semiconductor film is deposited to the thickness of 500˜1000 Å on the semiconductor film by a PECVD device, and when depositing the doped semiconductor film, the reaction gas in the PECVD device is the mixture gas of SiH₄, PH₃, and H₂, or the mixture gas of SiH₂Cl₂, PH₃, and H₂.

S132, photoresist is applied on the doped semiconductor film, and is exposed and developed by using a mask plate to form a photoresist fully remaining area B and a photoresist fully removing area A, and the photoresist fully remaining area B corresponds to the pattern area of the semiconductor layer, and a portion of the doped semiconductor film is exposed by the photoresist fully removing area A.

S133, the semiconductor film and the doped semiconductor film in the photoresist fully removing area A are etched to form a semiconductor layer 003 and a doped semiconductor layer 004a, and to obtain the structure as illustrated in FIG. 7.

Thus, the semiconductor layer 003 and the doped semiconductor layer 004a having the same shape can be formed by a single patterning process, and the photoresist 20a located on the semiconductor layer and the doped semiconductor layer can be remained.

(2) During the process of the step S15, after lifting off the channel position photoresist part 20b and the source/drain metal film thereon, and prior to patterning the remained source/drain metal film, the method further comprises etching the doped semiconductor layer corresponding to the gate electrode 11 to expose the semiconductor layer.

That is to say, the step S15 comprises:

S151, a source/drain metal film is formed on the substrate with the channel position photoresist part 20b, and the channel position photoresist part 20b and the source/drain metal film located thereon are lift off, to obtain a structure as illustrated in FIG. 8.

S152, by an etching process, the doped semiconductor layer 004a corresponding to the gate electrode 11 is etched to expose the semiconductor layer 003 at the channel position, to form a doped semiconductor pattern 004b, and obtain a structure as illustrated in FIG. 9.

S153, the remained source/drain metal film is patterned to form a source electrode 12 and a drain electrode 13, and to obtain a structure as illustrated in FIG. 10.

The second method for manufacturing a thin film transistor containing doped semiconductor patter is different from the above manufacture method in that:

During the step S14 is carried out, prior to forming the source/drain metal film, the method further comprises forming a doped semiconductor film on the substrate having the channel position photoresist part 20b; here, forming the source/drain metal film on the substrate having the channel position photoresist part 20b, in fact, is forming the source/drain metal film on the doped semiconductor film. In addition, at the same time as lifting off the channel position photoresist part 20b and the source/drain metal film thereon, the doped semiconductor film located between the channel position photoresist part 20b and the source/drain metal film is also lift off; when forming the source electrode and the drain electrode by a patterning process, a doped semiconductor pattern is also formed; the doped semiconductor pattern is identical with the pattern of the source and drain electrodes.

That is to say, the step S15 further comprises:

S151′, a doped semiconductor film is formed on the substrate having the channel position photoresist part 20b, and a source/drain metal film is also formed on the doped semiconductor film;

S152′, the channel position photoresist part 20b and the doped semiconductor film and the source/drain metal film located over the channel position photoresist part are together lift off;

S153′, by a single patterning process, the doped semiconductor pattern as well and the source and drain electrodes are formed, and the doped semiconductor pattern is identical with the pattern of the source and drain electrodes.

Any method for manufacturing a thin film transistor as above provided may further comprises, after preparation of the source electrode and the drain electrode are finished, forming a passivation layer covering the source electrode, the channel and the drain electrode to protect the structure of the thin film transistor.

In the method for manufacturing a thin film transistor as provided by the embodiments of the present invention, exposure and development are carried out from a side of the transparent substrate opposite to the side on which the gate electrode is formed by using the gate electrode as a mask, to form a channel position photoresist part corresponding to the gate electrode, and after that, the channel position photoresist part and the source/drain metal film located thereon are removed by a lifting-off process, so as to form the source electrode and the drain electrode aligned precisely with the gate electrode, and thus the product quality is improved.

An embodiment of the present invention provides a method for manufacturing an array substrate, since the array substrate comprises thin film transistors, FIGS. 1 to 6 may still be referred. In addition, the materials, thicknesses of each film layers and the preparation condition may refer to the above mentioned embodiment, and thus will not described in detail any more. The method for manufacturing an array substrate comprises:

S21, as illustrated in FIG. 1, a gate metal layer is formed on a transparent substrate 001; the gate metal layer comprises a gate line (not shown) and a gate electrode 11 of a thin film transistor.

In particularly, the gate metal film is deposited on the transparent substrate 001, and a gate metal layer is formed by a patterning process.

S22, as illustrated in FIG. 2, a gate insulation layer 002 is formed on the substrate provided with the gate metal layer.

S23, as illustrated in FIG. 2, a transparent semiconductor film is formed on the gate insulation layer 002, and a semiconductor layer 003 is formed by a patterning process with the photoresist 20a above the semiconductor layer 003 remained.

S24, as shown in FIG. 3, the remained photoresist 20a is exposed and developed from a side of the transparent substrate 001 opposite to the side on which the gate electrode 11 is formed by using the gate electrode 11 as a mask, to form a channel position photoresist part 20b at least corresponding to the gate electrode 11.

The difference from the above method for manufacturing the thin film transistor lies in: the corresponding step in the method for manufacturing the thin film transistor uses the gate electrode pattern as the pattern of the mask, while for the method for manufacturing the array substrate as provided by the present embodiment, the pattern of the gate metal layer is used as the pattern of the mask.

In the embodiments of the present invention, generally, the area of the semiconductor layer pattern is larger than the area of the gate electrode pattern so that the photoresist 20a located in the area of the semiconductor layer pattern forms the channel position photoresist part 20b corresponding to the gate electrode, after being back exposure. Since the array substrate is further provided with the gate line, if the semiconductor layer pattern area is enlarged so as to have an overlap portion with the gate line pattern area, then the channel position photoresist part 20b as formed not only corresponds to the gate electrode, but also corresponds to the semiconductor layer pattern in the overlap portion.

S25, as illustrated in FIG. 4, a source/drain metal film 101 is formed on the substrate with the channel position photoresist part 20b, and referring to FIG. 5, the channel position photoresist part 20b and the source/drain metal film thereon are lift off and further referring to FIG. 6, a source/drain metal layer is formed by a patterning process. The source/drain metal layer comprises a data line (not shown) and the source electrode 12 and the drain electrode 13 of the thin film transistor.

Optionally, after the step S25, the method may further comprise forming a passivation layer and a pixel electrode by the means known in the related art.

Preferably, in order to reduce the amount of the patterning processes, in the embodiments of the present invention, a method in which only a single patterning process is carried out to form the source/drain metal layer and the pixel electrode is provided. In particularly, during the step S25, prior to forming the source/drain metal film, the method further comprises forming a transparent conductive film on the substrate with the channel position photoresist part 20b, at this time, forming of the source/drain metal film on the substrate with the channel position photoresist part may be forming the source/drain metal film on the transparent conductive film. In addition, while lifting off the channel position photoresist part 20b and the source/drain metal film thereon, the transparent conductive film located between the channel position photoresist part 20b and the source/drain metal film is also lift off. Accordingly, when the source/drain metal layer by the patterning process is formed, the pixel electrode is also formed.

That is to say, referring to FIG. 11 to FIG. 13, the above step S25 may comprise:

S251, as illustrated in FIG. 11, a transparent conductive film 102 is formed on the substrate with the channel position photoresist part 20b and the source/drain metal film 101 is formed on the transparent conductive film 102.

By way of example, firstly a transparent conductive film 102 with a thickness of 500˜1500 Å may be deposited by sputtering or thermal evaporation process, and the material for the transparent conductive film 102 may be indium tin oxide, indium zinc oxide, or aluminum zinc oxide, or may be other transparent conductive material; subsequently a source/drain metal film 101 with a thickness of 2000˜3000 Å may be deposited on the transparent conductive film 102, and the material for the source/drain metal layer may be a metal such as molybdenum, aluminum, copper or tungsten or a composition film layer composed of several metals.

S252, as illustrated in FIG. 12, the channel position photoresist part 20b and the transparent conductive film and the source/drain metal film that are located on the channel position photoresist part 20b are lift off.

S253, with the remained transparent conductive film and the source/drain metal film, by a single patterning process, the pixel electrode 14 and the source/drain metal layer are formed, to obtain the structure as illustrated in FIG. 13. The source/drain metal layer comprises a data line (not shown), a source electrode 12 and a drain electrode 13.

The photoresist can be divided into three areas as illustrated in FIG. 12, and the step S253 may specially comprise:

S2531, after lifting off the channel position photoresist part 20b along with the transparent conductive film and the source/drain metal film located thereon, photoresist is applied, and exposed and developed by using a grey level mask plate or a translucent mask plate to form a photoresist fully remaining area B, a photoresist half remaining area C, and a photoresist fully removing area A. The source/drain metal film is exposed through the photoresist fully removing area A, and the photoresist fully remaining area B corresponds to the pattern area of the source/drain metal layer and the channel area, while the photoresist half remaining area C corresponds to the pattern area of the pixel electrode.

S2532, the transparent conductive film and the source/drain metal film in the photoresist fully removing area A is etched to obtain the pixel electrode 14;

S2533, the photoresist in the photoresist half remaining area C is removed by an ashing process, and the source/drain metal film exposed from the photoresist half remaining area C is etched to obtain the source/drain metal layer comprising a data line, a source electrode 12 and a drain electrode 13.

S2534, the photoresist in the photoresist fully remaining area B is lift off.

Hereinafter, a method for manufacturing an array substrate containing a doped semiconductor pattern is provided, this method is based on the above mentioned manufacturing method of an array substrate, and therefore only the difference from the above mentioned method is described in detail below.

This method for manufacturing an array substrate containing a doped semiconductor pattern is different from the above manufacturing method of an array substrate in that:

(1) During the process of the step S23, after forming the transparent semiconductor film and prior to forming the semiconductor layer by a patterning process, the present method further comprises forming a doped semiconductor film on the semiconductor film, and a doped semiconductor layer is formed when forming the semiconductor layer by a patterning process, the shape of the semiconductor layer and the shape of the doped semiconductor layer are the same.

That is to say, the above S23 comprises:

S231, a transparent semiconductor film is formed on the gate insulation layer, and a doped semiconductor film is formed on the semiconductor film;

S232, referring to FIG. 7, photoresist is applied on the doped semiconductor film, and is exposed and developed by using a mask plate to form a photoresist fully remaining area B and a photoresist fully removing area A. The doped semiconductor film is exposed from the photoresist fully removing area A, and the photoresist fully remaining area B corresponds to the pattern area of the semiconductor layer.

S233, the semiconductor film and the doped semiconductor film in the photoresist fully removing area A are etched to form a semiconductor layer 003 and a doped semiconductor layer 004a.

Thus, the semiconductor layer 003 and the doped semiconductor layer 004a having same shape can be formed by a single patterning process, and the photoresist 20a above the semiconductor layer 003 and the doped semiconductor layer 004a is remained.

(2) During the process of the step S25, after lifting off the channel position photoresist part along with the transparent conductive film and the source/drain metal film located thereon, and prior to patterning the remained transparent conductive film and the source/drain metal film, the present method further comprises: etching the doped semiconductor layer corresponding to the gate electrode to expose the semiconductor layer at the channel position, to form the doped semiconductor pattern.

That is to say, the above step S25 comprises:

S251′, as illustrated in FIG. 14, a transparent conductive film 102 and a source/drain metal film 101 are sequentially formed on the substrate with the channel position photoresist part 20b;

S252′, as illustrated in FIG. 15, the channel position photoresist part 20b and the transparent conductive film and the source/drain metal film that are located on the channel position photoresist part 20b are lift off;

S253′, by an etching process, the doped semiconductor layer 004a corresponding to the gate electrode II is etched to expose the semiconductor layer and form the doped semiconductor pattern 004b, as illustrated in FIG. 16;

S254′, the remained transparent conductive film and the source/drain metal film is subjected to a patterning process to form the source/drain metal layer, comprising the source electrode 12, the drain electrode 13 and the data line, and the pixel electrode 14, as illustrated in FIG. 17.

Furthermore, as illustrated in FIG. 18, a passivation layer 005 may be further formed after the step S25.

With the method for manufacturing an array substrate as provided by any of the embodiments of the present invention, the channel of the thin film transistor on the array substrate is obtained by back exposure with the gate electrode as a mask plate, thus the gate electrode can be precisely aligned with the source/drain electrode, whereby the product quality is improved. In addition, the source/drain electrode and the pixel electrode are formed by a single patterning process, and the manufacturing costs are reduced.

What are described above is related to the illustrative embodiments of the disclosure only and not limitative to the scope of the disclosure; the scopes of the disclosure are defined by the accompanying claims.

1. A method for manufacturing a thin film transistor comprises:
forming a gate electrode on a transparent substrate;
forming a gate insulation layer;
forming a transparent semiconductor film and patterning the transparent semiconductor film to form a semiconductor layer with photoresist being remained over the semiconductor layer;
from a side of the transparent substrate opposite to the side on which the gate electrode is formed, exposing and developing the remained photoresist by using the gate electrode as a mask to form a channel position photoresist part corresponding to the gate electrode;
forming a source/drain metal film and lifting off the channel position photoresist part and the source/drain metal film located over the channel position photoresist part; and
patterning the remained source/drain metal film to form a source electrode and a drain electrode.

2. The method according to claim 1, wherein the method further comprises, after forming the transparent semiconductor film and prior to patterning the semiconductor film, forming a doped semiconductor film on the semiconductor film;
wherein when the semiconductor film is patterned, the doped semiconductor film is patterned at the same time to form a doped semiconductor layer, and a shape of the semiconductor layer is identical with a shape of the doped semiconductor layer; and
wherein the method further comprises, after lifting off the channel position photoresist part and the source/drain metal film thereon and prior to patterning the remained source/drain film, etching the doped semiconductor layer corresponding to the gate electrode to expose the semiconductor layer and form a doped semiconductor pattern.

3. The method according to claim 2, wherein forming of the doped semiconductor layer comprises:
applying photoresist on the doped semiconductor film and exposing, developing to form a photoresist fully remaining area corresponding to a pattern area of the semiconductor layer and a photoresist fully removing area through which the doped semiconductor film is exposed;
etching the semiconductor film and the doped semiconductor film in the photoresist fully removing area to form the semiconductor layer and the doped semiconductor layer.

4. The method according to claim 1, wherein the method further comprises, prior to the forming the source/drain metal film, forming a doped semiconductor film on the substrate on which the channel position photoresist part is formed;
wherein upon lifting off the channel position photoresist part and the source/drain metal film thereon, the doped semiconductor film between the channel position photoresist part and the source/drain metal film is also lift off at the same time; and
wherein upon patterning the remained source/drain metal film to form the source electrode and the drain electrode, the doped semiconductor film is patterned at the same time to form a doped semiconductor pattern, the doped semiconductor pattern being identical with the source electrode and the drain electrode in shape.

5. A method for manufacturing an array substrate comprises:
forming a gate metal layer on a transparent substrate, the gate metal layer comprising a gate line and a gate electrode of a thin film transistor;
forming a gate insulation layer;
forming a transparent semiconductor film and patterning the semiconductor film to form a semiconductor layer with photoresist being remained over the semiconductor layer;
from a side of the transparent substrate opposite to the side on which the gate electrode is formed, exposing and developing the remained photoresist with the gate electrode as a mask, to form a channel position photoresist part corresponding to the gate electrode;
forming a source/drain metal film and lifting off the channel position photoresist part and the source/drain metal film thereon; and
patterning the remained source/drain metal film to form a source/drain metal layer, wherein the source/drain metal layer comprises a source electrode and a drain electrode of the thin film transistor and a data line.

6. The method according to claim 5, wherein the method further comprises, before the forming the source/drain metal film, forming a transparent conductive film on the substrate on which the channel position photoresist part is formed;
wherein forming of the source/drain metal film is to form the source/drain metal film on the transparent conductive film;
wherein upon lifting off the channel position photoresist part and the source/drain metal film thereon, the transparent conductive film between the channel position photoresist part and the source/drain metal film is also lift off; and
wherein upon patterning the remained source/drain metal film to form the source/drain metal layer, the transparent conductive film is also patterned at the same time to form a pixel electrode.

7. The method according to claim 6, wherein forming of the pixel electrode comprises:
on the substrate on which the channel position photoresist part along with the transparent conductive film and the source/drain metal film thereon has been lift off, applying photoresist, and exposing and developing to form a photoresist fully remaining area, a photoresist half remaining area and a photoresist fully removing area, wherein the photoresist fully remaining area corresponds to a pattern area of the source/drain metal layer and a channel area, the photoresist half remaining area corresponds to a pattern area of the pixel electrode, and the photoresist fully removing area exposes the source/drain metal film; and
etching the transparent conductive film and the source/drain metal film in the photoresist fully removing area to form the pixel electrode;
removing the photoresist in the photoresist half remaining area by an ashing process, and etching the source/drain metal film exposed from the photoresist half remaining area to form the source/drain metal layer; and
lifting off the photoresist in the photoresist fully remaining area.

8. The method according to claim 7, wherein the method further comprises, after forming the transparent semiconductor film and prior to patterning the semiconductor film, forming a doped semiconductor film on the semiconductor film;
wherein upon forming the semiconductor layer, the doped semiconductor film is also patterned at the same time to form a doped semiconductor layer, a shape of the semiconductor layer is identical with a shape of the doped semiconductor layer; and
wherein the method further comprises, after lifting off the channel position photoresist part along with the transparent conductive film and the source/drain metal film thereon and prior to patterning the remained source/drain metal film, etching the doped semiconductor layer corresponding to the gate electrode to expose the semiconductor layer and form the doped semiconductor layer.

9. The method according to claim 8, wherein patterning of the semiconductor layer and the doped semiconductor layer comprises:
applying photoresist on the doped semiconductor film, and exposing and developing by using a mask plate to form a photoresist fully remaining area corresponding to a pattern area of the semiconductor layer and a photoresist fully removing area from which the doped semiconductor film is exposed; and
etching the semiconductor film and the doped semiconductor film in the photoresist fully removing area to form the semiconductor layer and the doped semiconductor layer.

10. A thin film transistor manufactured by the method according to claim 1.
